(19) United States
(12) Patent Application Publication
(10) Pub. No.: US 2021/0340672 A1
(43) Pub. Date: Nov. 4, 2021

(54) Plasma Assisted Parylene Deposition

(71) Applicant: HZO, Inc., Morrisville, NC (US)

(72) Inventors: Robert Eugene Askin, III, Cary, NC (US); Sean Owen Clancy, Apex, NC (US)

(21) Appl. No.: 16/863,659

(22) Filed: Apr. 30, 2020

(51) Int. Cl. C23C 16/448; C08G 61/02; C23C 16/52; C23C 14/12; B05D 1/00; H01J 37/32

(52) U.S. Cl. CPC C23C 16/4485; C08G 61/025; H01J 37/3244; C23C 14/12; B05D 1/62; C23C 16/52

(57) ABSTRACT

A method for depositing parylene onto a substrate includes utilizing a vaporization chamber and a pyrolysis chamber to crack a dimer into a monomer gas, directly ionizing the monomer gas by passing the monomer gas through a plasma generation chamber comprising plasma prior to injection of the monomer gas into a deposition chamber, and polymerizing the ionized monomer in the deposition chamber to create a polymer and a protective coating on a substrate.

### FIELD

This disclosure relates generally to plasma assisted parylene deposition. More specifically, this disclosure relates to ionizing a monomer gas, directly or indirectly, prior to or during deposition and polymerization of a protective coating.

### SUMMARY

The subject matter of the present application has been developed in response to the present state of the art, and in particular, in response to the problems and disadvantages associated with conventional parylene deposition that have not yet been fully solved by currently available techniques. Accordingly, the subject matter of the present application has been developed to provide embodiments that ionize a monomer gas, directly or indirectly, prior to or during deposition and polymerization of a protective coating, and with other features described herein overcome at least some of the shortcomings of prior art techniques.

Disclosed herein is a method for depositing parylene onto a substrate. The method includes utilizing a vaporization chamber and a pyrolysis chamber to crack a dimer into a monomer gas, directly ionizing the monomer gas by passing the monomer gas through a plasma generation chamber comprising plasma prior to injection of the monomer gas into a deposition chamber, and polymerizing the ionized monomer in the deposition chamber to create a polymer and a protective coating on a substrate. The preceding subject matter of this paragraph characterizes example 1 of the present disclosure.

The method further includes modifying radicals of the monomer gas with the plasma, wherein the modification increases the reactivity of the radicals. The preceding subject matter of this paragraph characterizes example 2 of the present disclosure, wherein example 2 also includes the subject matter according to example 1, above.

The monomer gas is ionized between the pyrolysis chamber and the deposition chamber. The preceding subject matter of this paragraph characterizes example 3 of the present disclosure, wherein example 3 also includes the subject matter according to any one of examples 1-2, above.

The plasma is generated by a plasma generation system, where the plasma generation system is a radio frequency plasma generation system. The preceding subject matter of this paragraph characterizes example 4 of the present disclosure, wherein example 4 also includes the subject matter according to any one of examples 1-3, above.

The plasma is generated by a plasma generation system, where the plasma generation system is a pulsed direct current plasma generation system. The preceding subject matter of this paragraph characterizes example 5 of the present disclosure, wherein example 5 also includes the subject matter according to any one of examples 1-4, above.

The polymer on the substrate is a parylene N coating. The preceding subject matter of this paragraph characterizes example 6 of the present disclosure, wherein example 6 also includes the subject matter according to any one of examples 1-5, above.

The polymer on the substrate is a parylene F coating. The preceding subject matter of this paragraph characterizes example 7 of the present disclosure, wherein example 7 also includes the subject matter according to any one of examples 1-6, above.

The monomer is a parylene monomer. The preceding subject matter of this paragraph characterizes example 8 of the present disclosure, wherein example 8 also includes the subject matter according to any one of examples 1-7, above.

Disclosed herein is a method for depositing parylene onto a substrate. The method includes injecting a monomer gas into a deposition chamber, injecting a plasma into the deposition chamber, the plasma generated in a plasma generation chamber, ionizing the monomer gas with the plasma to generate ionized monomer, and polymerizing the ionized monomer to create a polymer and a protective coating on a substrate. The preceding subject matter of this paragraph characterizes example 9 of the present disclosure.

The method includes modifying radicals of the monomer gas with the plasma, wherein the modification increases the reactivity of the radicals. The preceding subject matter of this paragraph characterizes example 10 of the present disclosure, wherein example 10 also includes the subject matter according to example 9, above.

The plasma is generated by a plasma generation system, where the plasma generation system is a radio frequency plasma generation system. The preceding subject matter of this paragraph characterizes example 11 of the present disclosure, wherein example 11 also includes the subject matter according to any one of examples 9-10, above.

The plasma is generated by a plasma generation system, where the plasma generation system is a pulsed direct current plasma generation system. The preceding subject matter of this paragraph characterizes example 12 of the present disclosure, wherein example 12 also includes the subject matter according to any one of examples 9-10, above

The polymer on the substrate is a parylene N or parylene F coating. The preceding subject matter of this paragraph characterizes example 13 of the present disclosure, wherein example 13 also includes the subject matter according to any one of examples 9-12, above.

The method includes energizing the monomer gas after cracking dimer. The preceding subject matter of this paragraph characterizes example 14 of the present disclosure, wherein example 14 also includes the subject matter according to any one of examples 9-13, above.

The method includes utilizing a vaporization chamber and a pyrolysis chamber to crack a dimer into a monomer gas, and wherein the monomer is a parylene monomer. The preceding subject matter of this paragraph characterizes example 15 of the present disclosure, wherein example 15 also includes the subject matter according to any one of examples 9-14, above.

Disclosed herein is a system. The system includes a pyrolysis chamber configured to crack a dimer into a monomer gas, a plasma generation system configured to generate a plasma, and a deposition chamber configured to facilitate polymerization of an ionized monomer gas into a polymer and a protective coating on a substrate. The preceding subject matter of this paragraph characterizes example 16 of the present disclosure.

The plasma generation system is coupled to a plasma generation chamber, wherein the plasm generation chamber is positioned between the pyrolysis chamber and the deposition chamber. The preceding subject matter of this paragraph characterizes example 17 of the present disclosure, wherein example 17 also includes the subject matter according to example 16, above.

The plasma generation system is a radio frequency plasma generation system. The preceding subject matter of this paragraph characterizes example 18 of the present disclosure, wherein example 18 also includes the subject matter according to any one of examples 16-17, above.

The plasma generation system is a pulsed direct current plasma generation system. The preceding subject matter of this paragraph characterizes example 19 of the present disclosure, wherein example 19 also includes the subject matter according to any one of examples 16-18, above.

The plasma generation system is coupled to deposition chamber, wherein the plasma generation system is configured to inject plasma into the deposition chamber. The preceding subject matter of this paragraph characterizes example 20 of the present disclosure, wherein example 20 also includes the subject matter according to any one of examples 16-19, above.

The described features, structures, advantages, and/or characteristics of the subject matter of the present disclosure may be combined in any suitable manner in one or more embodiments and/or implementations. In the following description, numerous specific details are provided to impart a thorough understanding of embodiments of the subject matter of the present disclosure. One skilled in the relevant art will recognize that the subject matter of the present disclosure may be practiced without one or more of the specific features, details, components, materials, and/or methods of a particular embodiment or implementation. In other instances, additional features and advantages may be recognized in certain embodiments and/or implementations that may not be present in all embodiments or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific embodiments that are illustrated in the appended drawings. Understanding that these drawings depict only typical embodiments of the subject matter and are not therefore to be considered to be limiting of its scope, the subject matter will be described and explained with additional specificity and detail through the use of the drawings, in which:

FIG. 1 is a schematic diagram of a system, according to one or more embodiments of the present disclosure;

FIG. 2 is a parylene deposition system, according to one or more embodiments of the present disclosure;

FIG. 3 is a parylene deposition system, according to one or more embodiments of the present disclosure;

FIG. 4 is a parylene deposition system, according to one or more embodiments of the present disclosure;

FIG. 5 is a schematic block diagram of a method for depositing parylene onto a substrate, according to one or more embodiments of the present disclosure; and

FIG. 6 is a schematic block diagram of a method for depositing parylene onto a substrate, according to one or more embodiments of the present disclosure.

### DETAILED DESCRIPTION

Reference throughout this specification to “one embodiment,” “an embodiment,” or similar language means that a particular feature, structure, or characteristic described in connection with the embodiment is included in at least one embodiment of the present disclosure. Appearances of the phrases “in one embodiment,” “in an embodiment,” and similar language throughout this specification may, but do not necessarily, all refer to the same embodiment. Similarly, the use of the term “implementation” means an implementation having a particular feature, structure, or characteristic described in connection with one or more embodiments of the present disclosure, however, absent an express correlation to indicate otherwise, an implementation may be associated with one or more embodiments.

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

Other aspects, as well as features and advantages of various aspects, of the disclosed subject matter will be apparent to those of ordinary skill in the art through consideration of this disclosure and the appended claims.

Moisture resistant coatings or films, as well as other coatings or films are used to protect various parts of electronic devices (or substrates) from external influences. Protective coatings, such as parylene, are deposited on parts of the electronic devices in deposition chambers. Parylene, and other protective coatings, are deposited on the parts of electronic devices in various methods and processes. Some of those processes, examples of which are described by U.S. Patent Application Publication Nos. 2009/0263581, 2009/0263641, 2009/0304549, 2010/0203347, 2010/0293812, and 2011/0262740, the entire disclosures of each of which are, by this reference, incorporated herein. The disclosures describe embodiments of equipment and/or processes that may be employed to apply a protective coating.

Various types of parylene exist including parylene C (poly(chloro-p-xylylene)), parylene F (which can specifically refer to parylene-VT4, parylene-AF4, or any other parylene with a fluorine atom or atoms in the molecular structure), parylene N (poly(p-xylylene)), parylene D (poly(dichloro-p-xylylene)), parylene A (amino-modified parylene), etc.

The various types of parylene have different features, benefits, and drawbacks when compared with each other. For example, the deposition time of parylene N is significantly longer than the deposition time for parylene C. The longer deposition time increases manufacturing time and costs. As another example, while parylene C provides quality water protection or water resistance, parylene C does not provide ultraviolet (UV) protection. While parylene F provides quality UV protection and high temperature protection, parylene F is more expensive than parylene N, as much as thirty-five times more expensive.

The high-quality properties of parylene F make it desirable for many applications but the high cost of parylene F make it unsuitable in many situations for economic reasons. In addition, parylene N and parylene F are slow to deposit on a substrate or electronic device because they are less reactive than, for example, a parylene C. The lower reactiveness of parylene N and parylene F may also result in a large amount of unreacted material flowing through the deposition chamber as waste in cold traps. Further, parylene N and parylene F may also have larger deposition times, taking more time on valuable equipment.

Embodiments described herein provide increasing the reactivity of Parylene N and Parylene F with application of a plasma. Embodiments described herein facilitate quicker reactivity of parylene N and parylene F. Parylene F can specifically refer to parylene-VT4, parylene-AF4, or any other parylene with a fluorine atom or atoms in the molecular structure and parylene N may refer to poly(p-xylylene). In some embodiments, the monomer (after cracking) is passed through a plasma generator before entering the deposition chamber. In some embodiments, the monomer gas is directly ionized prior to entering the deposition chamber.

In some embodiments, plasma from a plasma generator is generated in a remote location and injected into deposition chamber with the monomers. Some embodiments described herein provide faster deposition and less waste resulting in a higher yield of protective coating. In addition, in some embodiments, new co-polymer structures are produced.

In some embodiments, the plasma is applied to the dimer and the plasma energizes or removes energy from the system resulting in cracking the dimer to create the monomer. In some embodiments, a plasma generator system may be utilized in the pyrolysis chamber to enhance cracking and result in quicker cracking and quicker deposition. In some embodiments, the plasma excites the radicals of the monomers and in some cases can excite the electrons to a higher state and create higher reactivity within the monomers or greater polarity in the monomers.

A method is disclosed. The method includes directly ionizing a monomer gas by passing the monomer gas through a plasma generator prior to injection in a deposition chamber. The method includes polymerizing the monomer to create a protective coating on a substrate.

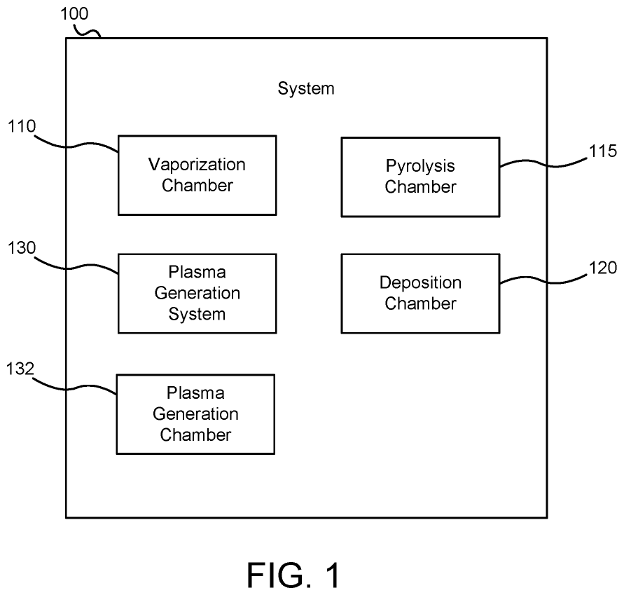

Referring now to FIG. 1, a schematic diagram of a system for efficiently depositing parylene is shown. Although the system 100 is shown and described with certain components and functionality, other embodiments of the system 100 may include fewer or more components to implement less or more functionality. The system 100 includes a vaporization chamber 110, pyrolysis chamber 115, a deposition chamber 120, a plasma generation system 130, and a plasma generation chamber 132.

The illustrated system 100 may also include processors, such as control processors, configured to control operations of the system 100, either alone or in conjunction with various processing sub-systems integrated into other systems or modules within the system 100. For example, the processor may communicate electronically with modules or other systems included in various embodiments described and contemplated herein.

The processor may include software capable of carrying out part or all of the functionality described in any methods, steps, processes, or other functional descriptions of the system 100 and its component sub-systems.

In some embodiments, the system 100 includes a vaporization chamber 110. The vaporization chamber 110 may include a repository or receptacle configured to hold a precursor. The vaporization chamber 110 may include various valves and other components that allow the vaporization chamber 110 to hold, vaporize, and distribute a precursor to the pyrolysis chamber 115.

In some embodiments, the system 100 includes a pyrolysis chamber 115. The pyrolysis chamber 115 may include a repository or receptacle configured to hold a precursor. The pyrolysis chamber 115 may include various valves and other components that allow the pyrolysis chamber 115 to hold, pyrolyze, and distribute a precursor to the plasma generation chamber 132 or the deposition chamber 130.

The precursor may refer to a dimer before cracking or a monomer after cracking. In some embodiments, the monomer is a monomer gas. In some embodiments, the monomer is a precursor for a type of parylene. In some embodiments, the parylene is parylene F or parylene N, although other types of parylene may be used. The monomer is a representative monomer used to apply a protective coating on a substrate or electronic device. Other embodiments of monomers are contemplated.

Referring again to FIG. 1, the system includes a plasma generation system 130. In some embodiments, the monomer gas is energized by plasma generated in a plasma generation system 130. In some embodiments, the monomer is polymerized by the plasma generation system 130. In some embodiments, the monomer is energized by a capacitively coupled RF plasma source. In some embodiments, the monomer is polymerized by a pulsed DC plasma source. Other forms of energy generation are contemplated herein. The plasma generation system 130 may be a pulsed direct current (pulsed DC) plasma generation system or a radio frequency (RF) plasma generation system, or another type of plasma generator.

In some embodiments, the plasma generation system 130 ionized the monomer before the monomer enters the deposition chamber 120. In some embodiments, the plasma generation system 130 ionizes the monomer within a plasma generation chamber 132. In some embodiments, the plasma generation system 130 ionizes the monomer within the deposition chamber 120. In some embodiments, the plasma generation system 130 energizes the monomer in a conduit that conducts the monomer from the pyrolysis chamber 115 to the deposition chamber 120. As such, the plasma generation system 130 may be coupled directly to the pyrolysis chamber 115, the deposition chamber 120, the plasma generation chamber 132, a conduit between the pyrolysis chamber 115 and the deposition chamber 120, or another separate chamber.

The plasma generation system 130 may be coupled directly to the deposition chamber 120 in various locations to allow the monomer to flow through or by the plasma that is generated. This may occur in the deposition chamber 120, in the conduit, or in the plasma generation chamber 132. In some embodiments, a monomer source intake is on a same side of the deposition chamber 120 as the plasma generation system 130. In some embodiments, the monomer source intake is on an opposite side of the deposition chamber 120 from the plasma generation system 130.

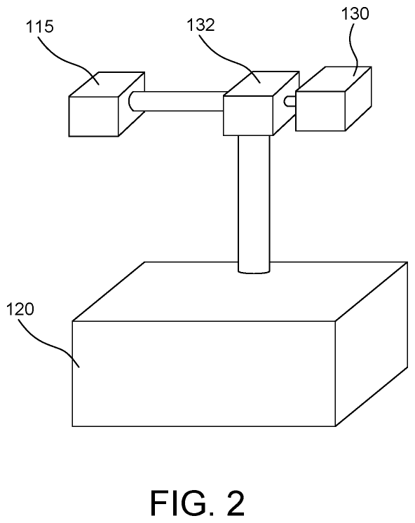

Referring now to FIG. 2, a parylene deposition system is shown. The system includes a pyrolysis chamber 115 which is configured to crack the dimer, a plasma generation system 130 which is configured to generate the plasma, a plasma generation chamber 132 which is configured to mix the monomer from the pyrolysis chamber 115 with the plasma of the plasma generation system 130. The system also includes a deposition chamber 120 in which the monomer that has been ionized or energized by the plasma is deposited upon substrates as the monomers polymerize into a protective coating on the substrates. The plasma is configured to ionize the monomer gas. In some embodiments, the plasma modifies the radicals of the monomer gas, thereby increasing the reactivity of the radicals and increasing the rate of deposition and decreasing the overall deposition time of the parylene. Reducing the deposition time of parylenes, especially parylene F or parylene N, is beneficial because of the typically long deposition times that are associated with those parylenes.

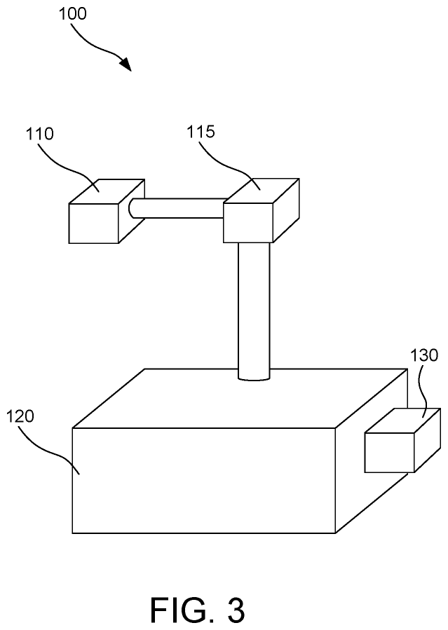

Referring now to FIG. 3, a parylene deposition system 100 is shown. The system 100 includes a vaporization chamber 110, a pyrolysis chamber 115, and a deposition chamber 120. The system 100 also includes a plasma generation system 130 coupled to the deposition chamber 120. The plasma generation system 130 is configured to generate plasma within the deposition chamber 120. The monomer produced in the pyrolysis chamber 115 and fed into the deposition chamber 120 will pass through the plasma and will be ionized or energized by the plasma, thereby increasing the reactivity of the radicals and increasing the rate of deposition and decreasing the overall deposition time of the parylene.

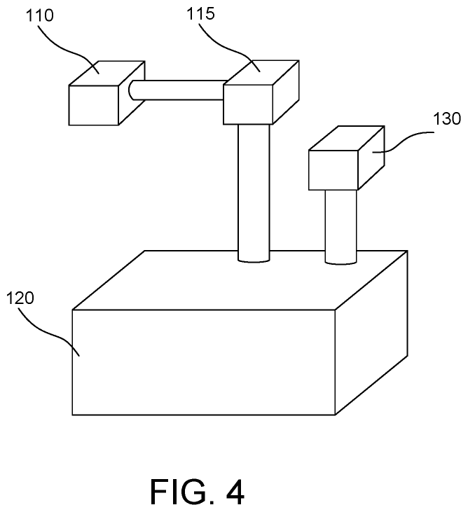

Referring now to FIG. 4, a parylene deposition system is shown. The system includes a vaporization chamber 110, a pyrolysis chamber 115, and a deposition chamber 120. The system 100 also includes a plasma generation system 130 which is configured to inject plasma into the deposition chamber 120. The plasma generation system 130 is configured to generate plasma and inject the plasma into the deposition chamber 120 near the injection position of the monomer. The monomer produced in the pyrolysis chamber 115 and fed into the deposition chamber 120 will pass through the plasma that is injected into the deposition chamber 120 and will be ionized or energized by the plasma, thereby increasing the reactivity of the radicals and increasing the rate of deposition and decreasing the overall deposition time of the parylene.

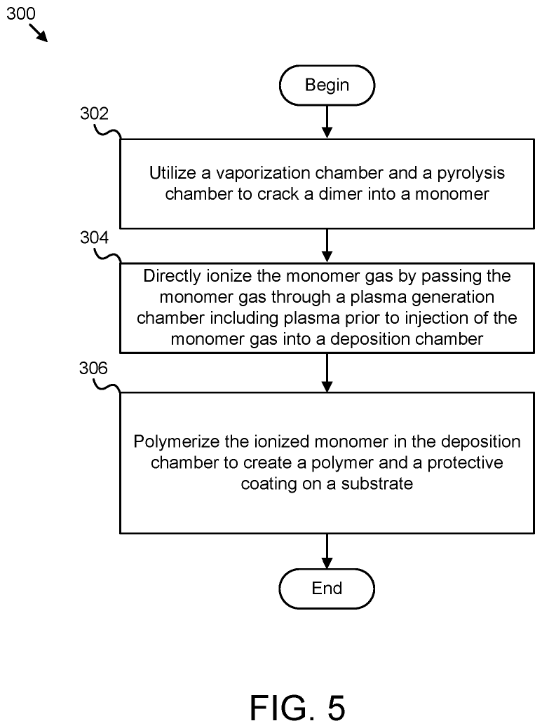

Referring to FIG. 5, a method 300 is disclosed. At block 302, the method 300 includes utilizing a vaporization chamber and a pyrolysis chamber to crack a dimer into a monomer gas. At block 304, the method 300 includes directly ionizing the monomer gas by passing the monomer gas through a plasma generation chamber comprising plasma prior to injection of the monomer gas into a deposition chamber. At block 306, the method 300 includes polymerizing the ionized monomer in the deposition chamber to create a polymer and a protective coating on a substrate. The method 300 then ends.

In some embodiments, the method further includes modifying radicals of the monomer gas with the plasma, wherein the modification increases the reactivity of the radicals. Types of plasma that may be used include, but are not limited to, O₂, Ar, SF₆, C₄F₈, C₃F₆, CF₄, fluorocarbon gases, fluorinated gases, and halogenated gases, and other similar gases.

In some embodiments, the monomer gas is energized or ionized before entering the deposition chamber. This may occur in a separate chamber or in transit from the pyrolysis chamber to the deposition chamber. In some embodiments, the monomer gas is ionized or energized within the deposition chamber. In some embodiments, the monomer gas is ionized or energized in a conduit that conducts the monomer gas from the pyrolysis chamber to the deposition chamber. Other methods of delivering the monomer gas to the deposition chamber are also contemplated herein and are not discussed for the sake of brevity but may include utilizing pressure differential.

In some embodiments, the monomer gas is a parylene precursor monomer. In some embodiments, the monomer gas is a parylene precursor monomer for parylene F. In some embodiments, the monomer gas is a parylene precursor monomer for parylene N. As the deposition times for parylene F and parylene N typically take substantial time, ionizing the monomer gas may energize the monomer gas to deposit more quickly.

In some embodiments, the plasma of the plasma generation chamber is produced by a capacitively-coupled radio frequency (RF) plasma generation system. In some embodiments, the RF plasma generation system is coupled directly to the deposition chamber to generate the plasma within the deposition chamber. In some embodiments, the RF plasma generation system generates the plasma outside the deposition chamber and is then transported into the deposition chamber. In some embodiments, the RF plasma generation system generates the plasma in the plasma generation chamber and energizes the monomer in the plasma generation chamber. In some embodiments, the RF plasma generation system generates the plasma to energize the monomer gas in a conduit that conducts the monomer gas from the pyrolysis chamber to the deposition chamber. In some embodiments, the RF plasma generation system is remote from the deposition chamber.

In some embodiments, the plasma of the plasma generation chamber is produced by a pulsed direct current (pulsed DC) plasma generation system. In some embodiments, the pulsed DC plasma generation system is coupled directly to the deposition chamber to generate the plasma within the deposition chamber. In some embodiments, the pulsed DC plasma generation system generates the plasma outside the deposition chamber and is then transported into the deposition chamber. In some embodiments, the pulsed DC plasma generation system generates the plasma in the plasma generation chamber and energizes the monomer in the plasma generation chamber. In some embodiments, the pulsed DC plasma generation system generates the plasma to energize the monomer gas in a conduit that conducts the monomer gas from the pyrolysis chamber to the deposition chamber. In some embodiments, the pulsed DC plasma generation system is remote from the deposition chamber.

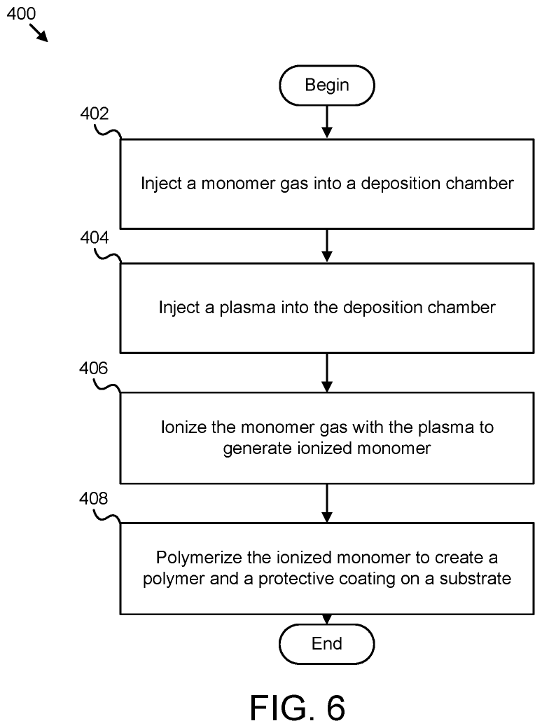

Referring to FIG. 6, a method 400 is disclosed. At block 402, the method 400 includes injecting a monomer gas into a deposition chamber. At block 404, the method 400 includes injecting a plasma into the deposition chamber, the plasma generated in a plasma generation chamber. At block 406, the method 400 includes ionizing the monomer gas with the plasma to generate ionized monomer. At block 408, the method 400 includes polymerizing the ionized monomer to create a polymer and a protective coating on a substrate. The method 400 then ends.

In some embodiments, the method further includes modifying radicals of the monomer gas with the plasma, wherein the modification increases the reactivity of the radicals.

In some embodiments, the monomer gas is energized or ionized before entering the deposition chamber. This may occur in a separate chamber or in transit from the pyrolysis chamber to the deposition chamber. In some embodiments, the monomer gas is ionized or energized within the deposition chamber. In some embodiments, the monomer gas is ionized or energized in a conduit that conducts the monomer gas from the pyrolysis chamber to the deposition chamber. Other methods of delivering the monomer gas to the deposition chamber are also contemplated herein and are not discussed for the sake of brevity but may include utilizing pressure differential.

In some embodiments, the monomer gas is a parylene precursor monomer. In some embodiments, the monomer gas is a parylene precursor monomer for parylene F. In some embodiments, the monomer gas is a parylene precursor monomer for parylene N. As the deposition times for parylene F and parylene N typically take substantial time, ionizing the monomer gas may energize the monomer gas to deposit more quickly.

In some embodiments, the plasma of the plasma generation chamber is produced by a capacitively-coupled radio frequency (RF) plasma generation system. In some embodiments, the RF plasma generation system is coupled directly to the deposition chamber to generate the plasma within the deposition chamber. In some embodiments, the RF plasma generation system generates the plasma outside the deposition chamber and is then transported into the deposition chamber. In some embodiments, the RF plasma generation system generates the plasma in the plasma generation chamber and energizes the monomer in the plasma generation chamber. In some embodiments, the RF plasma generation system generates the plasma to energize the monomer gas in a conduit that conducts the monomer gas from the pyrolysis chamber to the deposition chamber. In some embodiments, the RF plasma generation system is remote from the deposition chamber.

In some embodiments, the plasma of the plasma generation chamber is produced by a pulsed direct current (pulsed DC) plasma generation system. In some embodiments, the pulsed DC plasma generation system is coupled directly to the deposition chamber to generate the plasma within the deposition chamber. In some embodiments, the pulsed DC plasma generation system generates the plasma outside the deposition chamber and is then transported into the deposition chamber. In some embodiments, the pulsed DC plasma generation system generates the plasma in the plasma generation chamber and energizes the monomer in the plasma generation chamber. In some embodiments, the pulsed DC plasma generation system generates the plasma to energize the monomer gas in a conduit that conducts the monomer gas from the pyrolysis chamber to the deposition chamber. In some embodiments, the pulsed DC plasma generation system is remote from the deposition chamber.

Although the foregoing disclosure provides many specifics, these should not be construed as limiting the scope of any of the ensuing claims. Other embodiments may be devised which do not depart from the scopes of the claims. Features from different embodiments may be employed in combination. The scope of each claim is, therefore, indicated and limited only by its plain language and the full scope of available legal equivalents to its elements.

Reference throughout this specification to features, advantages, or similar language does not imply that all of the features and advantages that may be realized with the subject matter of the present disclosure should be or are in any single embodiment. Rather, language referring to the features and advantages is understood to mean that a specific feature, advantage, or characteristic described in connection with an embodiment is included in at least one embodiment of the present disclosure. Thus, discussion of the features and advantages, and similar language, throughout this specification may, but do not necessarily, refer to the same embodiment.

In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

The present subject matter may be embodied in other specific forms without departing from its spirit or essential characteristics. The described embodiments are to be considered in all respects only as illustrative and not restrictive.

In the above description, specific details of various embodiments are provided. However, some embodiments may be practiced with less than all of these specific details. In other instances, certain methods, procedures, components, structures, and/or functions are described in no more detail than to enable the various embodiments of the invention, for the sake of brevity and clarity.

What is claimed:

1. A method for depositing parylene onto a substrate, comprising:
utilizing a vaporization chamber and a pyrolysis chamber to crack a dimer into a monomer gas;
directly ionizing the monomer gas by passing the monomer gas through a plasma generation chamber comprising plasma prior to injection of the monomer gas into a deposition chamber;
polymerizing the ionized monomer in the deposition chamber to create a polymer and a protective coating on a substrate.

2. The method of claim 1, further comprising modifying radicals of the monomer gas with the plasma, wherein the modification increases the reactivity of the radicals.

3. The method of claim 1, wherein the monomer gas is ionized between the pyrolysis chamber and the deposition chamber.

4. The method of claim 1, wherein the plasma is generated by a plasma generation system, where the plasma generation system is a radio frequency plasma generation system.

5. The method of claim 1, wherein the plasma is generated by a plasma generation system, where the plasma generation system is a pulsed direct current plasma generation system.

6. The method of claim 1, wherein the polymer on the substrate is a parylene N coating.

7. The method of claim 1, wherein the polymer on the substrate is a parylene F coating.

8. The method of claim 8, wherein the monomer is a parylene monomer.

9. A method for depositing parylene onto a substrate, comprising:
injecting a monomer gas into a deposition chamber;
injecting a plasma into the deposition chamber, the plasma generated in a plasma generation chamber;
ionizing the monomer gas with the plasma to generate ionized monomer; and
polymerizing the ionized monomer to create a polymer and a protective coating on a substrate.

10. The method of claim 9, further comprising modifying radicals of the monomer gas with the plasma, wherein the modification increases the reactivity of the radicals.

11. The method of claim 9, wherein the plasma is generated by a plasma generation system, where the plasma generation system is a radio frequency plasma generation system.

12. The method of claim 9, wherein the plasma is generated by a plasma generation system, where the plasma generation system is a pulsed direct current plasma generation system.

13. The method of claim 9, wherein the polymer on the substrate is a parylene N or parylene F coating.

14. The method of claim 9, further comprising energizing the monomer gas after cracking dimer.

15. The method of claim 9, further comprising utilizing a vaporization chamber and a pyrolysis chamber to crack a dimer into a monomer gas, and wherein the monomer is a parylene monomer.

16. A system comprising:
a pyrolysis chamber configured to crack a dimer into a monomer gas;
a plasma generation system configured to generate a plasma;
a deposition chamber configured to facilitate polymerization of an ionized monomer gas into a polymer and a protective coating on a substrate.

17. The system of claim 16, wherein the plasma generation system is coupled to a plasma generation chamber, wherein the plasm generation chamber is positioned between the pyrolysis chamber and the deposition chamber.

18. The system of claim 16, wherein the plasma generation system is a radio frequency plasma generation system.

19. The system of claim 16, wherein the plasma generation system is a pulsed direct current plasma generation system.

20. The system of claim 16, wherein the plasma generation system is coupled to deposition chamber, wherein the plasma generation system is configured to inject plasma into the deposition chamber.
